(19) United States
(12) Patent Application Publication
(10) Pub. No.: US 2026/0367527 A1
(43) Pub. Date: Nov. 19, 2026

(54) A FLUID HANDLING SYSTEM AND METHOD

(71) Applicant: ASML NETHERLANDS B.V., Veldhoven (NL)

(72) Inventors: Marc Léon VAN DER GAAG, Rheden (NL); Justin Johannes Hermanus GERRITZEN, Veldhoven (NL); Shruthi NAYAK KALLARBAIL, Eindhoven (NL); Milena JOVANOVIC, Eindhoven (NL)

(73) Assignee: ASML NETHERLANDS B.V., Veldhoven (NL)

(21) Appl. No.: 19/132,158

(22) PCT Filed: Nov. 23, 2023
(86) PCT No.: PCT/EP2023/082905

§ 371 Date: May 22, 2025

(30) Foreign Application Priority Data
Dec. 27, 2022 (EP) 22216821.3

(51) Int. Cl. G03F 7/00

(52) U.S. Cl. CPC G03F 7/70341

(57) ABSTRACT

A fluid handling system includes a liquid confinement structure, a gas supply conduit and a fluid transport conduit. The liquid confinement structure is configured to confine immersion fluid to a space between at least a part of the liquid confinement structure and a surface of a substrate. The gas supply conduit is configured to supply fluid to the space. The gas supply conduit has a flow controller configured to control the supply of gas from the gas supply conduit. The fluid transport conduit is configured to transport fluid extracted from the space. The fluid transport conduit has a flow meter configured to measure the flow of gas in the fluid transport conduit. Under a calibration mode, the gas supplied by the flow controller flows directly to the fluid transport conduit via a bypass conduit, wherein the bypass conduit bypasses the liquid confinement structure.

### CROSS-REFERENCE TO RELATED APPLICATIONS

This application claims priority of EP application 22216821.3 which was filed on 27 Dec. 2022 and which is incorporated herein in its entirety by reference.

### FIELD

The present invention relates to a fluid handling system and a method for calibrating a flow meter in a fluid handling system.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area, referred to as an immersion space, between a liquid confinement structure of the lithographic apparatus and the substrate by a fluid handling system. Fluid, for example carbon dioxide gas, is supplied to the immersion space by a flow controller. This supplied fluid is then extracted again from the immersion space by a fluid transport conduit system. In the fluid transport conduit system the flow is measured by a flow meter.

The performance of the fluid handling system may be sensitive to the flow settings of the supplied fluid through the immersion space. The accuracy of the flow controller and flow meter may be reduced due to drift over time.

### SUMMARY

It is an object of the present invention to provide a fluid handling system and method in which measures are taken to increase throughput and/or reduce defects on a substrate.

According to a first aspect of the invention, there is provided a fluid handling system comprising a liquid confinement structure, a gas supply conduit and a fluid transport conduit. The liquid confinement structure is configured to confine immersion fluid to a space between at least a part of the liquid confinement structure and a surface of a substrate. The gas supply conduit is in fluid communication with the liquid confinement structure and is configured to supply fluid to the space. The gas supply conduit has a flow controller configured to control the supply of gas from the gas supply conduit. The fluid transport conduit is in fluid communication with the liquid confinement structure and is configured to transport fluid extracted from the space. The fluid transport conduit has a flow meter configured to measure the flow of gas in the fluid transport conduit. Under a calibration mode, the gas supply conduit is in direct fluid communication with the fluid transport conduit via a bypass conduit, wherein the bypass conduit bypasses the liquid confinement structure, and the gas supplied by the flow controller flows directly to the fluid transport conduit via the bypass conduit.

According to a second aspect of the invention, there is provided a method for calibrating a flow meter in a fluid handling system. The fluid handling system comprising: a liquid confinement structure configured to confine immersion fluid to a space between at least a part of the liquid confinement structure and a surface of a substrate; a gas supply conduit in fluid communication with the liquid confinement structure and configured to supply fluid to the space, the gas supply conduit having a flow controller configured to control the supply of gas from the gas supply conduit; and a fluid transport conduit in fluid communication with the liquid confinement structure and configured to extract fluid from the space, the fluid transport conduit having the flow meter configured to measure the flow of gas in the fluid transport conduit. The method comprising: setting the system in calibration mode wherein the gas supply conduit is in direct fluid communication with the fluid transport conduit via a bypass conduit, and comparing the measured flow of gas in the fluid transport conduit against the flow of gas supplied by the flow controller. The bypass conduit bypasses the liquid confinement structure, and the gas supplied by the flow controller flows directly to the fluid transport conduit via the bypass conduit.

Further embodiments, features and advantages of the present invention, as well as the structure and operation of the various embodiments, features and advantages of the present invention, are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts the schematic overview of the lithographic apparatus;

FIGS. 2a, 2b, 2c and 2d each depict, in cross section, two different versions of a fluid handling system with different features illustrated on the left hand side and the right hand side of each version, which may extend around the complete circumference;

FIG. 3 depicts a fluid handling system including a gas supply conduit and a fluid transport conduit and a bypass conduit configured such that in a calibration mode the gas supply conduit is in direct fluid communication with the fluid transport conduit via the bypass conduit;

FIG. 4 depicts a fluid handling system comprising a gas supply conduit, a plurality of fluid transport conduits, and a corresponding plurality of bypass conduits, wherein each bypass conduit is configured such that in a calibration mode the gas supply conduit is in direct fluid communication with one of the plurality of fluid transport conduits via the corresponding bypass conduit;

FIG. 5 depicts a fluid handling system comprising a gas supply conduit, a plurality of fluid transport conduits, and a bypass conduit, wherein the bypass conduit is configured such that in a calibration mode the gas supply conduit is in direct fluid communication with one of the plurality of fluid transport conduits via the bypass conduit.

The features shown in the figures are not necessarily to scale, and the size and/or arrangement depicted is not limiting. It will be understood that the figures include optional features which may not be essential to the invention. Furthermore, not all of the features of the apparatus are depicted in each of the figures, and the figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

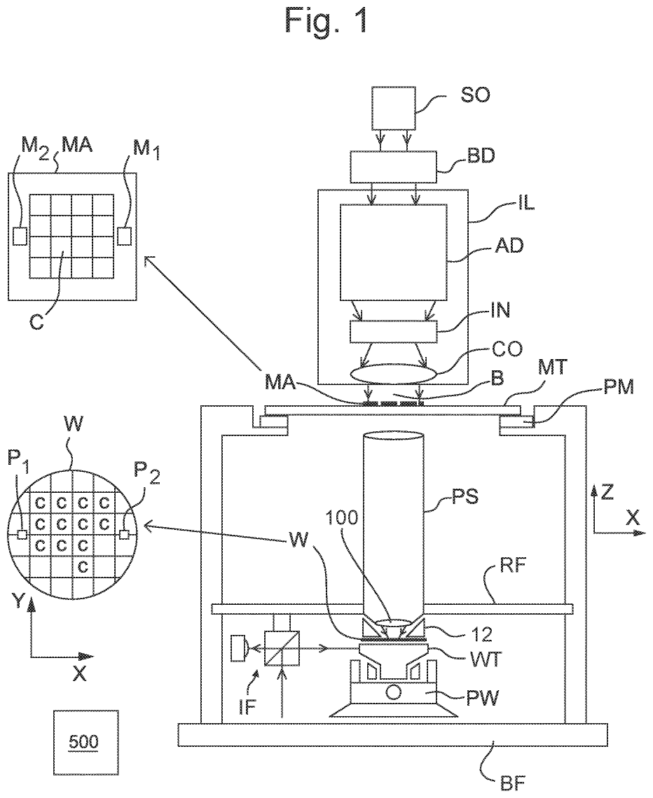

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W. A controller 500 controls the overall operation of the apparatus. Controller 500 may be a centralised control system or a system of multiple separate sub-controllers within various sub-systems of the lithographic apparatus.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W—which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid.

Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element 100 and a surface facing the final element 100. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure 12 present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element 100. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure 12 is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element 100 of the projection system PS and the substrate support WT or substrate W, so as to in part define the immersion space 11.

The fluid handing structure 12 may have a selection of different functions. Each function may be derived from a corresponding feature that enables the fluid handling structure 12 to achieve that function. The fluid handling structure 12 may be referred to by a number of different terms, each referring to a function, such as barrier member, seal member, fluid supply system, fluid removal system, liquid confinement structure, etc.

As a barrier member, the fluid handling structure 12 is a barrier to the flow of the immersion liquid from the immersion space 11. As a liquid confinement structure, the structure confines the immersion liquid to the immersion space 11. As a seal member, sealing features of the fluid handling structure 12 form a seal to confine the immersion liquid to the immersion space 11. The sealing features may include an additional gas flow from an opening in the surface of the seal member, such as a gas knife.

In an embodiment the fluid handling structure 12 may supply immersion fluid and therefore be a fluid supply system.

In an embodiment the fluid handling structure 12 may at least partly confine immersion fluid and thereby be a fluid confinement system.

In an embodiment the fluid handling structure 12 may provide a barrier to immersion fluid and thereby be a barrier member, such as a fluid confinement structure.

In an embodiment the fluid handling structure 12 may create or use a flow of gas, for example to help in controlling the flow and/or the position of the immersion fluid.

The flow of gas may form a seal to confine the immersion fluid so the fluid handling structure 12 may be referred to as a seal member; such a seal member may be a fluid confinement structure.

In an embodiment, immersion liquid is used as the immersion fluid. In that case the fluid handling structure 12 may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure 12 between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element 100 is at least partly surrounded by the fluid handling structure 12. The fluid handling structure 12 may confine the immersion liquid under the final element 100 and above the facing surface.

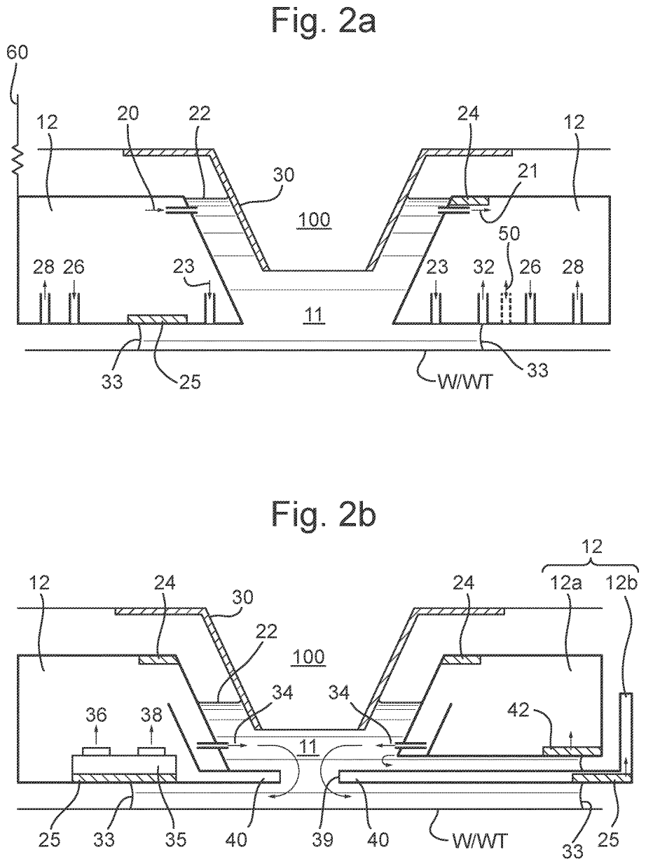

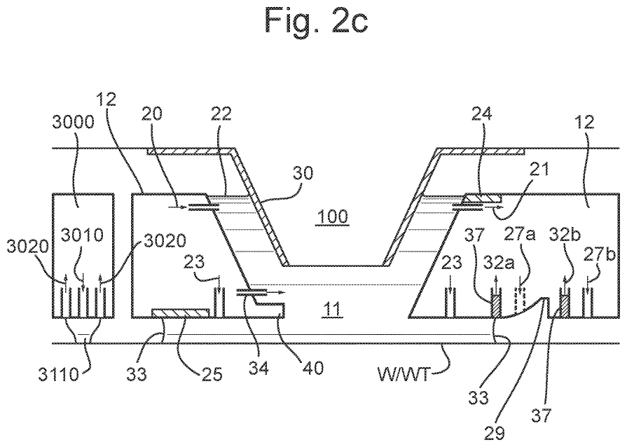

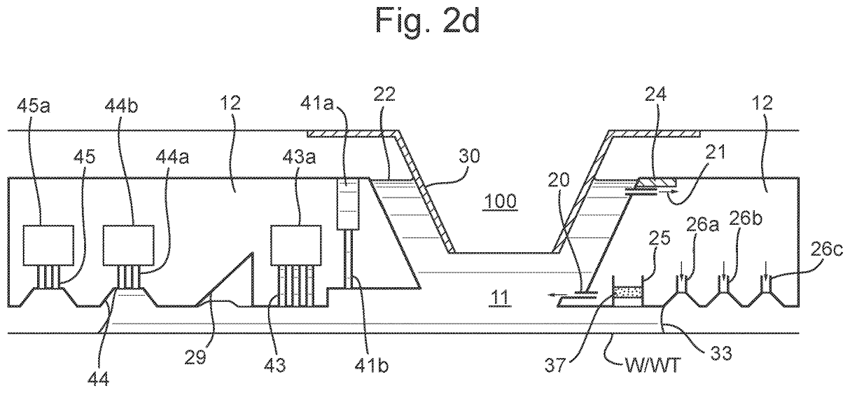

FIGS. 2a, 2b, 2c and 2d show different features which may be present in variations of a fluid handling system. The designs may share some of the same features as FIGS. 2a, 2b, 2c and 2d unless described differently. The features described herein may be selected individually or in combination as shown or as required. The figures depict different versions of a fluid handling system with different features illustrated on the left hand side and the right hand side, which may extend around the complete circumference. Thus, for example, the fluid handling system may have the same features extending around the complete circumference. For example, the fluid handling system may have only the features of the left hand side of FIG. 2a, or the right hand side of FIG. 2a, or the left hand side of FIG. 2b, or the right hand side of FIG. 2b, or the left hand side of 2c, or the right hand side of 2c, or the left hand side of 2d, or the right hand side of 2d. Alternatively, the fluid handling system may be provided with any combination of features from these figures at different locations around the circumference. The fluid handling system may comprise the fluid handling structure 12 as described in the variations below.

FIG. 2a shows a fluid handling structure 12 around the bottom surface of the final element 100. The final element 100 has an inverted frusto-conical shape. The frusto-conical shape having a planar bottom surface and a conical surface. The frusto-conical shape protrudes from a planar surface and having a bottom planar surface. The bottom planar surface is the optically active portion of the bottom surface of the final element 100, through which the radiation beam B may pass. The final element 100 may have a coating 30. The fluid handling structure 12 surrounds at least part of the frusto-conical shape. The fluid handling structure 12 has an inner-surface which faces towards the conical surface of the frusto-conical shape. The inner-surface and the conical surface may have complementary shapes. A top surface of the fluid handling structure 12 may be substantially planar. The fluid handling structure 12 may fit around the frusto-conical shape of the final element 100. A bottom surface of the fluid handling structure 12 may be substantially planar and in use the bottom surface may be parallel with the facing surface of the substrate support WT and/or substrate W. Thus, the bottom surface of the fluid handling structure 12 may be referred to as a surface facing the surface of the substrate W. The distance between the bottom surface and the facing surface may be in the range of 20 to 500 micrometers, desirably in the range of 70 to 200 micrometers.

The fluid handling structure 12 extends closer to the facing surface of the substrate W and substrate support WT than the final element 100. The immersion space 11 is therefore defined between the inner surface of the fluid handling structure 12, the planar surface of the frusto-conical portion and the facing surface. During use, the immersion space 11 is filled with immersion liquid. The immersion liquid fills at least part of a buffer space between the complementary surfaces between the final element 100 and the fluid handling structure 12, in an embodiment at least part of the space between the complementary inner-surface and the conical surface.

The immersion liquid is supplied to the immersion space 11 through an opening formed in a surface of the fluid handling structure 12. The immersion liquid may be supplied through a supply opening 20 in the inner-surface of the fluid handling structure 12. Alternatively or additionally, the immersion liquid is supplied from an under supply opening 23 formed in the bottom surface of the fluid handling structure 12. The under supply opening 23 may surround the path of the radiation beam B and it may be formed of a series of openings in an array or a single slit. The immersion liquid is supplied to fill the immersion space 11 so that flow through the immersion space 11 under the projection system PS is laminar. The supply of the immersion liquid from the under supply opening 23 additionally prevents the ingress of bubbles into the immersion space 11. This supply of the immersion liquid may function as a liquid seal.

The immersion liquid may be recovered from a recovery opening 21 formed in the inner-surface. The recovery of the immersion liquid through the recovery opening 21 may be by application of an underpressure; the recovery through the recovery opening 21 as a consequence of the velocity of the immersion liquid flow through the immersion space 11; or the recovery may be as a consequence of both. The recovery opening 21 may be located on the opposite side of the supply opening 20, when viewed in plan. Additionally or alternatively, the immersion liquid may be recovered through an overflow recovery 24 located on the top surface of the fluid handling structure 12. The supply opening 20 and recovery opening 21 can have their function swapped (i.e. the flow direction of liquid is reversed). This allows the direction of flow to be changed depending upon the relative motion of the fluid handling structure 12 and substrate W.

Additionally or alternatively, immersion liquid may be recovered from under the fluid handling structure 12 through a recovery opening 25 formed in its bottom surface. The recovery opening 25 may serve to hold a meniscus 33 of the immersion liquid to the fluid handling structure 12. The meniscus 33 forms between the fluid handling structure 12 and the facing surface and it serves as border between the liquid space and the gaseous external environment. The recovery opening 25 may be a porous plate which may recover the immersion liquid in a substantially single phase flow. The recovery opening in the bottom surface may be a series of pinning openings 32 through which the immersion liquid is recovered. The pinning openings 32 may recover the immersion liquid in a two phase flow.

Optionally radially outward, with respect to the inner-surface of the fluid handling structure 12, is a gas knife opening 26. Gas may be supplied through the gas knife opening 26 at elevated speed to assist liquid confinement of the immersion liquid in the immersion space 11. The supplied gas may be humidified and it may contain substantially carbon dioxide. Radially outward of the gas knife opening 26 is a gas recovery opening 28 for recovering the gas supplied through the gas knife opening 26.

Further openings, for example open to atmosphere or to a gas source or to a vacuum, may be present in the bottom surface of the fluid handling structure 12, i.e. in the surface of the fluid handling structure 12 facing the substrate W. An example of such an optional further opening 50 is shown in dashed lines on the right hand side of FIG. 2a. As shown, the further opening 50 may be a supply or extraction member, which is indicated by the double-headed arrow. For example, if configured as a supply, the further opening 50 may be connected to a liquid supply or a gas supply as with any of the supply members. Alternatively, if configured as an extraction, the further opening 50 may be used to extract fluid, and may for example, be connected to atmosphere or to a gas source or to a vacuum. For example, the at least one further opening 50 may be present between gas knife opening 26 and gas recovery opening 28, and/or between pinning openings 32 and gas knife opening 26.

The two different versions of the fluid handling structure 12 of the left and right sides of FIG. 2a pin the meniscus 33. The version of the fluid handling structure 12 on the right hand side of FIG. 2a may pin the meniscus 33 at a position that is substantially fixed with respect to the final element 100, due to the fixed position of the pinning opening 32. The version of the fluid handling structure 12 on the left hand side of FIG. 2a may pin the meniscus 33 below the recovery opening 25, and thus the meniscus 33 may move along the length and/or width of the recovery opening 25. For the radiation beam B to be directed to a full side of the substrate W under exposure, the substrate support WT supporting the substrate W is moved relative to the projection system PS. To maximize the output of substrates W exposed by the lithographic apparatus, the substrate support WT (and so substrate W) is moved as fast as possible. However, there is a critical relative speed (often referred to as a critical scan speed) above which the meniscus 33 between the fluid handling structure 12 and the substrate W becomes unstable. An unstable meniscus 33 has a greater risk of losing immersion liquid, for example in the form of one or more droplets. Furthermore, an unstable meniscus 33 has a greater risk of resulting in the inclusion of gas bubbles in the immersion liquid, especially when the confined immersion liquid crosses the edge of the substrate W.

A droplet present on the surface of the substrate W may apply a thermal load and may be a source of defectivity. The droplet may evaporate leaving a drying stain, it may move transporting contamination such as a particle, it may collide with a larger body of immersion liquid introducing a bubble of gas into the larger body and it may evaporate, applying the thermal heat load to the surface on which it is located. Such a thermal load could be a cause of distortion and/or a source of a positioning error if the surface is associated with positioning of components of the lithographic apparatus relative to the substrate W being imaged. A formation of a droplet on a surface is therefore is undesirable. To avoid formation of such a droplet, the speed of the substrate support WT is thus limited to the critical scan speed at which the meniscus 33 remains stable. This limits the throughput of the lithographic apparatus.

The left hand side of the fluid handling system in FIG. 2a may comprise a spring 60. The spring 60 may be an adjustable passive spring configured to apply a biasing force to the fluid handling structure 12 in the direction of the substrate W. Thus, the spring 60 can be used to control the height of the fluid handling structure 12 above the substrate W. Such adjustable passive springs are described in US 7,199,874 which is herein incorporated by reference in its entirety. Other bias devices may also be appropriate, for example, using an electromagnetic force. Although the spring 60 is shown with the left hand side of FIG. 2a, it is optional and does not need to be included with the other features of the left hand side of FIG. 2a. The spring 60 is not shown on any of the other figures, but could also be included with the other variations of the fluid handling system described in relation to FIGS. 2a, 2b, 2c, or 2d.

FIG. 2b shows two different versions of the fluid handling structure 12 on its left side and on its right side, which allow movement of the meniscus 33 with respect to the final element 100. The meniscus 33 may move in the direction of the moving substrate W. This decreases the relative speed between the meniscus 33 and the moving substrate W, which may result in improved stability and a reduced risk of breakdown of the meniscus 33. The speed of the substrate W at which the meniscus 33 breaks down is increased so as to allow faster movement of the substrate W under the projection system PS. Throughput is thus increased.

Features shown in FIG. 2b which are common to FIG. 2a share the same reference numbers. The fluid handling structure 12 has an inner surface which complements the conical surface of the frusto-conical shape. The bottom surface of the fluid handling structure 12 is closer to the facing surface than the bottom planar surface of the frusto-conical shape.

Immersion liquid is supplied to the immersion space 11 through supply openings 34 formed in the inner surface of the fluid handling structure 12. The supply openings 34 are located towards the bottom of the inner surface, perhaps below the bottom surface of the frusto-conical shape. The supply openings 34 are located around the inner surface, spaced apart around the path of the radiation beam B.

Immersion liquid is recovered from the immersion space 11 through recovery openings 25, in the bottom surface of the fluid handling structure 12. As the facing surface moves under the fluid handling structure 12, the meniscus 33 may migrate over the surface of the recovery opening 25 in the same direction as the movement of the facing surface. The recovery openings 25 may be formed of a porous member. The immersion liquid may be recovered in single phase. The immersion liquid may be recovered in a two phase flow. The two phase flow is received in a chamber 35 within the fluid handling structure 12 where it is separated into liquid and gas. The liquid and gas are recovered through separate channels 36, 38 from the chamber 35.

An inner periphery 39 of the bottom surface of fluid handling structure 12 extends into the immersion space 11 away from the inner surface to form a plate 40. The inner periphery 39 forms a small aperture which may be sized to match the shape and size of the radiation beam B. The plate 40 may serve to isolate the immersion liquid at either side of it. The supplied immersion liquid flows inwards towards the aperture, through the inner aperture and then under the plate 40 radially outwardly towards the surrounding the recovery openings 25.

The fluid handling structure 12 may be in two parts as shown on the right hand side of FIG. 2b: an inner part 12a and an outer part 12b. The inner part 12a and the outer part 12b may move relatively to each other, mainly in a plane parallel to facing surface. The inner part 12a may have the supply openings 34 and it may have the overflow recovery 24. The outer part 12b may have the plate 40 and the recovery opening 25. The inner part 12a may have an intermediate recovery 42 for recovering the immersion liquid which flows between the inner part 12a and the outer part 12b.

The two different versions of the fluid handling structure of FIG. 2b thus allow for movement of the meniscus 33 in the same direction as the substrate W, enabling faster scan speeds and increased throughput of the lithographic apparatus. However, the migration speed of meniscus 33 over the surface of the recovery opening 25 in the fluid handling structure 12 of the left side of FIG. 2b may be slow. The fluid handling structure 12 of the right side of FIG. 2b allows for quicker movement of the meniscus 33, by moving the outer part 12 b with respect to the inner part 12 a and the final element 100. However, it may be difficult to control the intermediate recovery 42 so as to ensure that enough immersion liquid is provided between the inner part 12a and the outer part 12b to prevent contact therebetween.

FIG. 2c shows two different versions of the fluid handling structure 12 on its left side and on its right side, which may be used to pin the meniscus 33 of the immersion liquid to the fluid handling structure 12 as described above in relation to FIGS. 2a and/or 2b. Features shown in FIG. 2c which are common to FIGS. 2a and/or 2b share the same reference numbers.

The fluid handling structure 12 has an inner surface which compliments the conical surface of the frusto-chronical shape. The bottom surface of the fluid handling structure 12 is closer to the facing surface than the bottom planar surface of the frusto-chronical shape. Immersion liquid is supplied to the immersion space 11 delivered through an opening formed in a surface of the fluid handling structure 12. The immersion liquid may be supplied through a supply opening 34 in the inner surface of the fluid structure 12. Alternatively or additionally, the immersion liquid may be supplied through a supply opening 20 in the inner surface of the fluid structure 12. Alternatively or additionally, the immersion liquid is supplied through the under supply opening 23. The immersion liquid may be recovered via an extraction member, for example, via recovery opening 21 formed in the inner-surface and/or overflow recovery 24 and/or one or more openings in a surface of the fluid handling structure 12 as described below.

The two different versions of the fluid handling structure 12 of the left and right sides of FIG. 2c pin the meniscus 33. The version of the fluid handling structure 12 on the right hand side of FIG. 2c may pin the meniscus 33 at a position that is substantially fixed with respect to the final element 100, due to the fixed position of the recovery opening 32a. The version of the fluid handling structure 12 on the left hand side of FIG. 2c may pin the meniscus 33 below the recovery opening 25, and thus the meniscus 33 may move along the length and/or width of the recovery opening 25.

As described above in relation to FIG. 2b, an inner periphery of the bottom surface of fluid handling structure 12 may extends into the immersion space 11 away from the inner surface to form a plate 40 as shown on the left hand side. As described above, this may form a small aperture, and may isolate the immersion liquid at either side and/or cause immersion liquid to flow inwards towards the aperture, through the inner aperture and then under the plate 40 radially outwardly towards the surrounding the recovery openings 25. Although this features is shown on the left hand side in FIG. 2c, it is optional in combination with the other features shown. Preferably, as shown on the left hand side, immersion liquid is supplied to the immersion space 11 through supply openings 34 formed in the inner surface of the fluid handling structure 12. The supply openings 34 are located towards the bottom of the inner surface, perhaps below the bottom surface of the frusto-conical shape. The supply openings 34 are located around the inner surface, spaced apart around the path of the radiation beam B. Alternatively or additionally, the immersion liquid may be supplied through a supply opening 20 in the inner surface of the fluid structure 12. Alternatively or additionally, the immersion liquid is supplied through the under supply opening 23. Although the supply openings 34 are the preferred liquid supply, any combination of supply openings 34, supply openings 20 and/or under supply openings 23 may be provided.

As shown on the left hand side of FIG. 2c, a fluid handling system may comprise the fluid handling structure 12 as described above and a further device 3000. The fluid handling structure 12 may have an extraction member, such as recovery opening 25, and a liquid supply opening, such as the under supply opening 23. It will be understood that the fluid handling structure 12 may comprise any configuration as disclosed in relation to the left hand of FIG. 2a, the right hand side of FIG. 2a, the left hand side of FIG. 2b, the right hand side of FIG. 2b or (as described below) the right hand side of FIG. 2c, in combination with the further device 3000.

The further device 3000 may otherwise be referred to as a droplet catcher. The further device 3000 is provided to reduce occurrence of liquid on the surface of the substrate W after the fluid handling structure 12 has moved over the surface. The further device 3000 may comprise a liquid supply member 3010 and at least one extraction member 3020. The at least one extraction member 3020 may be formed in a shape surrounding the at least one supply member 3010 in plan. The at least one liquid supply member 3010 may be configured to provide a further liquid to a space 3110 between at least a part of the further device 3000 and the surface of the substrate W. The further device 3000 may be configured to recover at least some of the liquid via the at least one extraction member 3020. The further device 3000 may be used to incorporate any liquid left on the surface of the substrate W with the liquid in the space 3110 and then use the further device 3000 to extract the liquid such that the amount of liquid remaining on the surface of the substrate W is reduced.

The further device 3000 is shown as a separate device from the fluid handling structure 12 in FIG. 2c. The further device 3000 may be positioned adjacent to the fluid handling structure 12. Alternatively, the further device 3000 may be part of, i.e. integral to, the fluid handling structure 12.

The further device 3000 may be configured to provide a liquid to the space 3110 which is separate from the liquid provided by the fluid handling structure 12.

Additionally or alternatively, the fluid handling structure 12 may have the components as shown on the right hand side of FIG. 2c. More specifically, the fluid handling structure 12 may comprise the at least one liquid supply member, two extraction members (e.g., recovery openings 32a and 32b) and two gas supply members (e.g., gas supply openings 27a and 27b) formed on the surface of the fluid handling structure 12. Gas supply opening 27a can be omitted, i.e. is optional. The at least one liquid supply member may be the same as the under supply opening 23 in the bottom surface of the fluid handling structure 12 described above or the supply opening 20 or liquid supply openings 34 formed on the inner surface of the fluid handling structure 12 described in relation to left hand side of FIG. 2b. The liquid supply member, the extraction members and the gas supply members may be formed on the surface of the fluid handling structure 12. Specifically, these components may be formed on a surface of the fluid handling structure 12 facing the substrate W, i.e. the bottom surface of the fluid handling structure 12.

At least one of the two extraction members may comprise a porous material 37 therein. The porous material 37 may be provided within an opening, e.g., recovery opening 32a through which fluid handling structure 12 extracts fluid from below the fluid handling structure 12 and may recover the immersion liquid in a single phase flow. The other of the two extraction members, e.g., recovery opening 32b may recover the immersion fluid as a dual phase extractor. The porous material 37 does not need to be flush with the bottom surface of the fluid handling structure 12.

Specifically, the fluid handling structure 12 may comprise the liquid supply member (e.g., under supply opening 23), with a first extraction member (e.g., recovery opening 32a) radially outwards of the liquid supply member, and a first gas supply member (e.g., gas supply opening 27a) radially outwards of the first extraction member, and the second extraction member (e.g., recovery opening 32b) radially outwards of the first gas supply member, and a second gas supply member (e.g., gas supply opening 27b) radially outwards of the second extraction member. Similar to FIG. 2a, further openings, for example open to atmosphere or to a gas source or to a vacuum, may be present in the bottom surface of the fluid handling structure 12 as described previously (in relation to the fluid handling structure 12).

For example, at least one further opening (not shown) may be provided in the bottom surface of the fluid handling structure 12. The further opening is optional. The further opening may be arranged between the first extraction member (e.g., recovery opening 32a) and the first gas supply member (e.g., gas supply opening 27a) as described in the arrangement above. Alternatively or additionally, the further opening may be arranged between the second extraction member (e.g., recovery opening 32b) and the second gas supply member (e.g., gas supply opening 27b) as described in the arrangement above. The further opening may be the same as further opening 50 described above.

Optionally, the fluid handling structure 12 comprises a recess 29. The recess 29 may be provided between the recovery opening 32a and recovery opening 32b or gas supply opening 27a and recovery opening 32b. The shape of the recess 29 may be uniform around the fluid handling structure 12 and may optionally contain an inclined surface. In the case of the recess 29 provided between the recovery opening 32a and recovery opening 32b, the gas supply opening 27b may be provided on the inclined surface as shown in FIG. 2c. In the case of the recess 29 provided between the supply opening 27a and recovery opening 32b, the gas supply opening 27b may be provided on the inclined surface or a part of the bottom surface of the fluid handling structure 12 which is parallel to the surface of the substrate W. Alternatively, the shape of the recess 29 may vary around the circumference of the fluid handling structure 12. The shape of the recess 29 may be varied to alter the impact of gas supplied from the gas supply members on the fluid below the fluid handling structure 12.

FIG. 2d shows, in its left and right halves, two different versions of the fluid handling structure 12. The fluid handling structure 12 of the left half of FIG. 2d has a liquid injection buffer 41a, which holds a buffer amount of immersion liquid, and liquid injection holes 41 which supply immersion liquid from the liquid injection buffer to the space 11. Outwardly of the liquid injection holes 41 are inner liquid recovery apertures 43 for conducting liquid to an inner recovery buffer 43a which is provided with a porous member. A recess 29 similar to that described relating to FIG. 2c is provided outward of the inner liquid recovery apertures 43. Outward of the recess 29, in the lower face of the fluid handling structure 12 is a gas guiding groove 44 into which open outer recovery holes 44a. The outer recovery holes 44a lead a two-phase recovery flow to outer recovery buffer 44b which is also provided with a porous member. Outermost are gas sealing holes 45 which communicate between a gas sealing buffer volume 45a and the space underneath the fluid handling structure 12 to provide a gas flow to contain the immersion liquid.

The fluid handling structure 12 of the right half of FIG. 2d has a liquid supply opening 20 in the inner inclined face thereof. In the underside of the fluid handling structure 12 there are (from inner side to outer side) an extraction opening 25 provided with a porous member 37; a first gas knife opening 26a, a second gas knife opening 26b and a third gas knife opening 26c. Each of these openings opens into a groove in the underside of the fluid handling structure 12 that provides a buffer volume. The outermost part of the fluid handling structure 12 is stepped so as to provide a greater separation between the fluid handling structure 12 and the substrate W.

FIGS. 2a-2d show examples of different configurations which can be used as part of a fluid handling system. It will be understood that the examples provided above refer to specific extraction members and recovery members, but it is not necessary to use the exact type of extraction member and/or recovery member. In some cases different terminology is used to indicate the position of the member, but the same functional features may be provided. Examples of the extraction member referred to above include recovery opening 21, overflow recover 24, recovery opening 25 (possibly comprising a porous plate and/or the chamber 35), gas recovery opening 28, pinning opening 32, recovery opening 32a, recovery opening 32b and/or the intermediate recovery 42. Examples of the supply member referred to above include supply opening 20, under supply opening 23, gas knife opening 26, gas supply opening 27a, gas supply opening 27b, and/or supply openings 34. In general, an extraction member used to extract/recover fluid, liquid or gas is interchangeable with at least any of the other examples used which extract/recover fluid, liquid or gas respectively. Similarly, a supply member used to supply fluid, liquid or gas is interchangeable with at least any of the other examples used which supply fluid, liquid or gas respectively. The extraction member may extract/recover fluid, liquid or gas from a space by being connected to an underpressure which draws the fluid, liquid or gas into the extraction member. The supply member may supply fluid, liquid or gas to the space by being connected to a relevant supply.

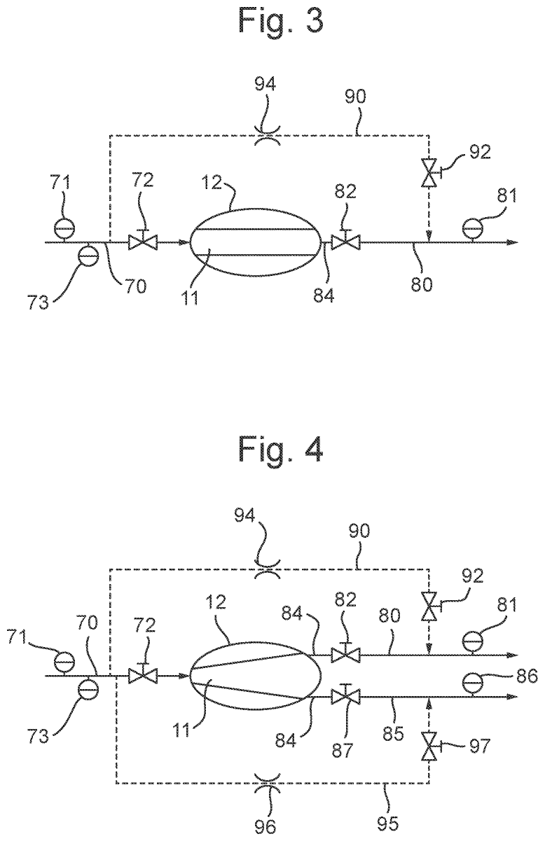

FIG. 3 depicts a fluid handling system comprising a fluid handling structure or a liquid confinement structure 12, a gas supply conduit 70, a fluid transport conduit 80, and a bypass conduit 90. The liquid confinement structure 12 is configured to confine immersion fluid to an immersion space 11 between at least a part of the liquid confinement structure 12 and a surface of a substrate.

For example, the fluid handling system, and/or in particular the fluid handling structure or liquid confinement structure 12 and corresponding immersion space 11, may be as described above with reference to any of FIGS. 1 and 2a-d.

The gas supply conduit 70 is in fluid communication with the liquid confinement structure 12. In particular, the gas supply conduit 70 is configured to supply fluid, for example a gas such as carbon dioxide, to the immersion space 11. The gas supply conduit 70 has a flow controller 71 configured to control the supply of fluid from the gas supply conduit 70. For example, the flow controller 71 may control the rate of flow of fluid through the gas supply conduit 70. The flow controller 71 is optionally a mass flow controller.

The fluid transport conduit 80 is in fluid communication with the liquid confinement structure 12. In particular, the fluid transport conduit 80 is configured to transport fluid, for example gas, extracted from the immersion space 11. The fluid extracted from the immersion space 11 may be a gas, for example carbon dioxide. In particular, the fluid extracted from the immersion space 11 is desirably the fluid supplied to the immersion space 11 by the gas supply conduit 70. The fluid transport conduit 80 has a flow meter configured to measure the flow of fluid in the fluid transport conduit 80.

In an production mode, the fluid supplied by the flow controller 71 flows to fluid transport conduit 80 via the liquid confinement structure 12. In other words, in the production mode, the gas supply conduit 70 supplies fluid to the immersion space 11, and the fluid from the immersion space 11 is transported by the fluid transport conduit 80. In the production mode, the flow meter 81 is configured to measure the flow of fluid through the fluid transport conduit 80. The flow meter 81 may therefore measure the flow of fluid, such as gas and/or liquid, extracted from the immersion space 11 between the liquid confinement structure 12 and the surface of the substrate. The flow meter 81 is optionally a gas flow meter. The flow meter 81 is desirably configured to measure fluid flow rate, more desirably the flow meter 81 is configured to measure mass flow rate.

Performance of the fluid handling system may be dependent on the flow of fluid into, through, and/or out of the liquid confinement structure 12. In particular, it may be beneficial to obtain an accurate measurement of the flow of fluid being supplied to and/or being transported from the immersion space 11.

In order to make sure that the flow measurement of the flow controller 71 supplying the fluid is correct, a measurement of the fluid pressure downstream of the flow controller 71 during normal operation may be performed. The geometry and the relationship between pressure and flow in this part of the system is relatively straightforward, and may have a linear relationship. As such, the pressure measurement(s) can be used to determine whether the flow controller 71 is providing a fluid flow rate at a sufficient level of accuracy. However, the relationship between pressure and flow through the liquid confinement structure 12 is more complicated. This is because, the flow in this part of the system is not only determined by the geometry of the hardware, but also by a variety of other factors including the amount of fluid supplied to the immersion space 11, the gap between the liquid confinement structure 12 and the sample and the contact angle of the sample. Because of this, any inaccuracy, for example due to drift over time, of the flow meter 81 cannot be determined very accurately by observation of changes in pressure of the fluid transport conduit system 80.

It is therefore desirable to provide a means to check that the flow meter 81 is calibrated such that the flow of fluid through the fluid transport conduit 80 is known to a sufficient level of accuracy. This may be achieved by a calibration mode of the fluid handling system.

In the calibration mode, the gas supply conduit 70 is in direct fluid communication with the fluid transport conduit 80 via a bypass conduit 90. The bypass conduit 90 bypasses the liquid confinement structure 12. In other words, in the calibration mode, the gas supply conduit 70 supplies fluid to the bypass conduit 90, instead of supplying fluid to the immersion space 11. The bypass conduit 90 transports the fluid from the gas supply conduit 70 to the fluid transport conduit 80.

In the calibration mode, the fluid supplied by the flow controller 71 flows directly to the fluid transport conduit 80 via the bypass conduit 90. The calibration mode may enable calibration of the flow meter 81 by comparison between the measured flow of fluid in the fluid transport conduit 80 against the flow of gas supplied by the flow controller 71.

In production mode the relationship between flow of fluid as supplied by the flow controller 71 of the gas supply conduit 70 and flow of fluid as measured by the flow meter 81 of the fluid transport conduit 80 may not be known due to the complexity of the geometry and flow in the immersion space 11 as defined by the liquid confinement structure 12 and the sample. In the calibration mode, the fluid flowing from the gas supply conduit 70 to the fluid transport conduit 80 bypasses the immersion space 11. The geometry and flow in the bypass conduit 90 is simpler than that of the immersion space 11. The bypass conduit 90 provides a direct flow channel between the flow controller 71 and the flow metre 81 such that all fluid from the flow controller 71 may be provided, through the bypass conduit 90, to the flow meter 81. In other words, in the calibration mode, there may be no flow outlets in the system between the flow controller 71 and the flow meter 81. A direct comparison between the flow provided by the flow controller 71 and the flow measured by the flow meter 81 may therefore be made. During normal operation, e.g., production mode, this is not the case because the immersion space 11 is an open environment and flow may be leaked or exit through other outlets such that all of the fluid does not reach the flow meter 81. Thus, in the calibration mode, a relationship between flow of fluid as supplied by the flow controller 71 of the gas supply conduit 70 and flow of fluid as measured by the flow meter 81 of the fluid transport conduit 80 may be known. Thus, if the flow controller 71 has been calibrated, it can be determined in the calibration mode whether the flow meter 81 is calibrated.

The fluid handling system may further comprise a comparator (not shown). Under the calibration mode, the comparator may be configured to compare the measured flow of fluid in the fluid transport conduit 80 against the flow of fluid supplied by the flow controller 71. In particular, the comparator may be configure to compare the flow measured by the flow meter 81 with the flow supplied by the flow controller 71.

As described above, there may be a known relationship between flow supplied by the flow controller 71 and flow through the fluid transport conduit 80 in the calibration mode. Thus, for a given flow provided by the flow controller 71, the flow through the fluid transport conduit 80 can be predetermined. The predetermined flow through the fluid transport conduit 80 based on the known relationship may be compared to the flow through the fluid transport conduit 80 measured by the flow meter 81. If the predetermined flow through the fluid transport conduit 80 and flow measured by the flow meter 81 match to within a predetermined range, the flow meter 81 may be considered to be calibrated. In other words, it may be determined that the flow meter 81 is providing sufficiently accurate measurement values of flow through the fluid transport conduit 80.

The fluid handling system optionally further comprise a meter calibration unit (not shown) configured to adjust the flow meter 81 based on the comparison. For example, if it is determined from the comparison that the flow meter 81 measurement is lower than expected, the flow meter 81 may be adjusted such that it gives the expected measurement value. Alternatively, or additionally, the fluid handling system may be configure to transmit an alert if the comparison indicates that the predetermined flow through the fluid transport conduit 80 and flow measured by the flow meter 81 do not match to within the predetermined range. In other words, the fluid handling system may be configured to alert a user if the flow meter 81 is not providing sufficiently accurate measurement values of flow through the fluid transport conduit 80. The user may then take action to adjust or replace the flow meter 81 as appropriate.

The bypass conduit 90 may be configured such that, in the calibration mode, both the gas supply conduit 70 and the fluid transport conduit 80 operate pressures similar, i.e., within a certain threshold range, of the pressures of the gas supply conduit 70 and the fluid transport conduit 80 in the production mode. The bypass conduit 90 is desirably configured such that, in the calibration mode, the pressure at the flow controller 71 and the flow meter 81 are similar, i.e., within a certain threshold range, of the pressures at the flow controller 71 and the flow meter 81 in the production mode. The bypass conduit 90 optionally comprises a flow restriction 94, for example as shown in FIG. 3. The flow restriction 94 may be configured to achieve the desired level of pressure in the fluid transport conduit 80 and/or the gas supply conduit 70 in the calibration mode.

The fluid handling system may comprise the bypass conduit 90. Alternatively, all or part of the bypass conduit 90 may be removable from the system. In the calibration mode the bypass conduit 90 is attached to the system and in the production mode the bypass conduit 90 is detached from the system. For example, the bypass conduit 90 may be configured to be disconnected from the gas supply conduit 70 and the fluid transport conduit 80 to set the system into production mode. To set the fluid handling system into the calibration mode, the bypass conduit 90 may be attached to the system. In other words, to set the fluid handling system into the calibration mode the bypass conduit 90 may be connected to the as supply conduit 70 and the fluid transport conduit 80. With this arrangement, the same bypass conduit 90 may be shared among a plurality of fluid handling systems by being disconnected from one system which has been calibrated, and connected to another system which may be in need of calibration. This is possible as the bypass conduit 90 is not used when the system is in production mode. This may beneficially make efficient use of components of the bypass conduit 90, thus saving costs.

As shown for example in FIG. 3, the fluid handling system may further comprise a plurality of valves. The plurality of valves may be configured to change the system between the production mode and the calibration mode. Alternatively, or additionally, for an arrangement wherein the bypass conduit 90 is removable, the plurality of valves may be configured to change the system between the production mode, wherein the bypass conduit 90 may be removed without hindering flow of fluid from the gas supply conduit 70 to the immersion space 11 and from the immersion space 11 through the fluid transport conduit 80, and the calibration mode.

In the exemplary arrangement shown in FIG. 3, the plurality of valves comprises a gas supply valve 72, a bypass valve 92, and a fluid extraction valve 82.

The gas supply valve 72 is disposed in the gas supply conduit 70. The gas supply valve 72 is desirably disposed downstream, in a direction of flow of fluid, of the flow controller 71. In other words, the gas supply valve 72 may be configured to allow, restrict and/or prevent flow from the gas supply conduit 70 to the immersion space 11. In particular, the gas supply valve 72 may be configured to allow, restrict and/or prevent flow of fluid provided by the flow controller 71 to the immersion space 11. In the production mode the gas supply valve 72 is open to allow fluid to flow from the gas supply conduit 70 into the immersion space 11. In the calibration mode, the gas supply valve 72 is closed to prevent fluid from flowing from the gas supply conduit 70 into the immersion space 11.

The bypass valve 92 is disposed in the bypass conduit 90. In other words, the bypass valve 92 may be configured to allow, restrict and/or prevent flow through the bypass conduit 90. In the production mode the bypass valve 92 is closed to prevent fluid from flowing from the gas supply conduit 70 to the fluid transport conduit 80 via the bypass conduit 90. In the calibration mode, the bypass valve 92 is open to allow fluid to flow from the gas supply conduit 70 to the fluid transport conduit 80 via the bypass conduit 90.

The fluid extraction valve 82 may be disposed in the fluid transport conduit 80 or at an inlet of the fluid transport conduit 80. The fluid extraction valve 82 is desirably disposed upstream of the flow meter 81. In other words, the fluid extraction valve 82 may be configured to allow, restrict and/or prevent flow from the immersion space 11 to the fluid transport conduit 80. In particular, the fluid extraction valve 82 may be configured to allow, restrict and/or prevent flow from the immersion space 11 to the flow meter 81. In the production mode, the fluid extraction valve 82 is open to allow fluid to flow from the immersion space 11 into the fluid transport conduit 80. In the calibration mode, the fluid extraction valve 82 is closed to prevent fluid from flowing from the immersion space 11 into the fluid transport conduit 80.

As shown in the exemplary arrangement of FIG. 3, the fluid handling system may comprise a fluid extraction conduit 84 in fluid communication with the liquid confinement structure 12 and configured to extract fluid from the immersion space 11 and direct the extracted fluid to the fluid transport conduit 80. The fluid extraction valve 82 may be disposed between the fluid extraction conduit 84 and the fluid transport conduit 80. In other words, the fluid extraction valve 82 may be configured to allow, restrict and/or prevent flow from the fluid extraction conduit 84 to the fluid transport conduit 80. In particular, the fluid extraction valve 82 may be configured to allow, restrict and/or prevent flow from fluid extraction conduit 84 to the flow meter 81. In the production mode, the fluid extraction valve 82 is open to allow fluid to flow from the fluid extraction conduit 84 into the fluid transport conduit 80. In the calibration mode, the fluid extraction valve 82 is closed to prevent fluid from flowing from the fluid extraction conduit 84 into the fluid transport conduit 80.

In at least production mode, immersion liquid is also supplied to immersion space 11 from liquid supply openings such as 20, 23, 34 from FIGS. 2a-2d such that fluid extraction conduit 84 extracts a two phase fluid, i.e., mixture of gas such as CO₂ and liquid such as water. The liquid supply and extraction circuit is not shown in FIG. 3. In such an arrangement, the two phase fluid may be separated before it reaches the flow meter 81, such that only single phase (e.g., gas) is measured by the flow meter 81. In particular, the separated phase of fluid (e.g., liquid) may be directed through a branch or outlet (not shown) between the immersion space 11 and the flow meter 81. Optionally, the separated phase of fluid may be directed through a branch or outlet disposed at a position between the fluid extraction conduit 84 and the flow meter 81, desirably between the fluid extraction conduit 84 and the position where the bypass conduit 90, or first branch 93 of the bypass conduit 90, connects to the fluid transport conduit 80, more desirably between the fluid extraction conduit 84 and the fluid extraction valve 82, i.e., upstream of the above mentioned position or fluid extraction valve 82. Similarly for the additional fluid transport conduit 85, single phase of the two phase fluid may be extracted before the fluid reaches the additional flow meter 86. The separated phase of fluid (e.g., liquid) may be directed through a branch or outlet (not shown) between the immersion space 11 and the additional flow meter 86. Optionally, the separated phase of fluid may be directed through a branch or outlet disposed at a position between the fluid extraction conduit 84 and the additional flow meter 86, desirably between the fluid extraction conduit 84 and the position where the additional bypass conduit 95, or second branch 98 of the bypass conduit, connects to the additional fluid transport conduit 85, more desirably between the fluid extraction conduit 84 and the additional fluid extraction valve 87, i.e., upstream of the above mentioned position or additional fluid extraction valve 87.

In an alternative arrangement (not shown in FIG. 3), the fluid handling system may comprise a plurality of fluid extraction conduits 84 in fluid communication with the liquid confinement structure 12 and configured to extract fluid from the immersion space 11 and direct the extracted fluid to the fluid transport conduit 80. The plurality of fluid extraction conduits 84 optionally merge downstream of the immersion space 11 to form the fluid transport conduit 80. In this arrangement, there may be a single fluid extraction valve 82 disposed at the inlet to, or at some point along, the fluid transport conduit 80 upstream of the flow meter 81. Alternatively, there may be two fluid extraction valves 82 disposed at some point along the fluid extraction conduits 84.

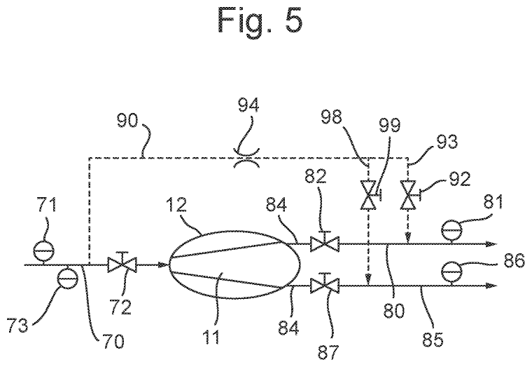

As shown in the exemplary arrangements of FIGS. 4 and 5, the fluid handling system optionally further comprises an additional fluid transport conduit 85 in fluid communication with the fluid handling structure or liquid confinement structure 12 and configured to transport fluid extracted from the immersion space 11. The additional fluid transport conduit 85 is provided with an additional flow meter 86 configured to measure the flow of fluid in the additional fluid transport conduit 85. In particular, the fluid in the additional fluid transport conduit 85 may be fluid supplied to the immersion space 11 via the gas supply conduit 70.

The fluid transport conduit 80 and the additional fluid transport conduit 85 may each be configured to transport fluid from the immersion space 11. As shown in FIGS. 4 and 5, the fluid handling system may comprise fluid extraction conduits 84. A first fluid extraction conduit 84 is in fluid communication with the liquid confinement structure 12 and configured to extract fluid from the immersion space 11 and direct the extracted fluid to the fluid transport conduit 80. A second fluid extraction conduit 84 is in fluid communication with the liquid confinement structure 12 and configured to extract fluid from the immersion space 11 and direct the extracted fluid to the additional fluid transport conduit 85. In an alternative arrangement (not shown), the fluid transport conduit 80 and the additional fluid transport conduit 85 may each be configured to extract fluid directly from the immersion space 11.

FIG. 4 depicts an exemplary fluid handling system comprising a gas supply conduit 70, a plurality of fluid transport conduits 80, 85, and a corresponding plurality of bypass conduits 90, 95. Each bypass conduit 90, 95 is configured such that in a calibration mode the gas supply conduit 70 is in direct fluid communication with one of the plurality of fluid transport conduits 80, 85 via the corresponding bypass conduit 90, 95.

Unless stated otherwise, the components of FIG. 4 having corresponding numbers perform the same function as described above for FIG. 3. As with the arrangement of FIG. 3 as described above, in the arrangement of FIG. 4 in the calibration mode, the gas supply conduit 70 is in direct fluid communication with the fluid transport conduit 80 via the bypass conduit 90, wherein the bypass conduit 90 bypasses the liquid confinement structure 12 and an additional bypass conduit 95. The fluid supplied by the flow controller 71 flows directly to the fluid transport conduit 80 via the bypass conduit 90.

In the arrangement of FIG. 4 in an additional calibration mode, the gas supply conduit 70 is in direct fluid communication with the additional fluid transport conduit 85 via the additional bypass conduit 95, wherein the additional bypass conduit 95 bypasses the liquid confinement structure 12 and the bypass conduit 90. The gas supplied by the flow controller 71 flows directly to the additional fluid transport conduit 85 via the additional bypass conduit 95.

As shown for example in FIG. 4, the fluid handling system may further comprise a plurality of valves. Similarly to the exemplary arrangement shown in FIG. 3, the plurality of valves of FIG. 4 comprises a gas supply valve 72, a bypass valve 92, and a fluid extraction valve 82, which are each configured as described above for FIG. 3. The plurality of valves of FIG. 4 further comprises an additional bypass valve 97 and an additional fluid extraction valve 87.

The additional bypass valve 97 is disposed in the additional bypass conduit 95. In other words, the additional bypass valve 97 may be configured to allow, restrict and/or prevent flow through the additional bypass conduit 95. In the production mode the bypass valve 97 is closed to prevent fluid from flowing from the gas supply conduit 70 to the additional fluid transport conduit 85 via the additional bypass conduit 95. In the calibration mode, the additional bypass valve 97 is closed to prevent fluid to flow from the gas supply conduit 70 to the additional fluid transport conduit 85 via the additional bypass conduit 95. In the additional calibration mode, the bypass valve 92 is closed to prevent fluid to flow from the gas supply conduit 70 to the fluid transport conduit 80 via the bypass conduit 90. In the additional calibration mode, the additional bypass valve 97 is open to allow fluid to flow from the gas supply conduit 70 to the additional fluid transport conduit 85 via the additional bypass conduit 95.

The additional fluid extraction valve 87 may be disposed in the additional fluid transport conduit 85 or at an inlet of the additional fluid transport conduit 85. The additional fluid extraction valve 87 is desirably disposed upstream of the additional flow meter 86. In other words, the additional fluid extraction valve 87 may be configured to allow, restrict and/or prevent flow from the immersion space 11 to the additional fluid transport conduit 85. In particular, the additional fluid extraction valve 87 may be configured to allow, restrict and/or prevent flow from the immersion space 11 to the additional flow meter 86. In the production mode, the additional fluid extraction valve 87 is open to allow fluid to flow from the immersion space 11 into the additional fluid transport conduit 85. In the additional calibration mode, the additional fluid extraction valve 87 is closed to prevent fluid from flowing from the immersion space 11 into the additional fluid transport conduit 85. In the additional calibration mode, the fluid extraction valve 82 is closed to prevent fluid from flowing from the immersion space 11 into the fluid transport conduit 80.

As shown in the exemplary arrangement of FIG. 5, the fluid handling system may comprise an additional fluid extraction conduit 84 in fluid communication with the liquid confinement structure 12 and configured to extract fluid from the space 11 and direct the extracted fluid to the additional fluid transport conduit 85. The additional fluid extraction valve 87 may be disposed between the fluid extraction conduit 84 and the additional fluid transport conduit 85. In other words, the additional fluid extraction valve 87 may be configured to allow, restrict and/or prevent flow from the fluid extraction conduit 84 to the additional fluid transport conduit 85. In particular, the additional fluid extraction valve 87 may be configured to allow, restrict and/or prevent flow from fluid extraction conduit 84 to the additional flow meter 86. In the production mode, the additional fluid extraction valve 87 is open to allow fluid to flow from the fluid extraction conduit 84 into the additional fluid transport conduit 85. In the calibration mode, the additional fluid extraction valve 87 is closed to prevent fluid from flowing from the fluid extraction conduit 84 into the additional fluid transport conduit 85. In the additional calibration mode, the additional fluid extraction valve 87 is closed to prevent fluid from flowing from the fluid extraction conduit 84 into the additional fluid transport conduit 85. In the additional calibration mode, the fluid extraction valve 82 is closed to prevent fluid from flowing from the fluid extraction conduit 84 into the fluid transport conduit 80.

FIG. 5 depicts a preferred arrangement wherein the fluid handling system comprises a gas supply conduit 70, a plurality of fluid transport conduits 80, 85, and a bypass conduit 90. In the arrangement of FIG. 5, the bypass conduit 90 is configured such that in a calibration mode the gas supply conduit 70 is in direct fluid communication with one of the plurality of fluid transport conduits 80, 85 via the bypass conduit 90. The bypass conduit 90 may comprise a first branch 93 configured to provide fluid communication between the gas supply conduit 70 and the fluid transport conduit 80.

The bypass conduit 90 may comprise a second branch 98 configured to provide fluid communication between the gas supply conduit 70 and the additional fluid transport conduit 85.

In the calibration mode, the gas supply conduit 70 is in direct fluid communication with the fluid transport conduit 80 via the first branch 93 of the bypass conduit 90, wherein the first branch 93 of the bypass conduit 90 bypasses the fluid handling structure or liquid confinement structure 12 and the second branch 98 of the bypass conduit 90. The fluid supplied by the flow controller 71 flows directly to the fluid transport conduit 80 via the bypass conduit 90.

In the arrangement of FIG. 5 in an additional calibration mode, the gas supply conduit 70 is in direct fluid communication with the additional fluid transport conduit 85 via the second branch 98 of the bypass conduit 90, wherein the second branch 98 of the bypass conduit 90 bypasses the liquid confinement structure 12 and the first branch 93 of the bypass conduit 90. The fluid supplied by the flow controller 71 flows directly to the additional fluid transport conduit 85 via the bypass conduit 90.

As shown for example in FIG. 5, the fluid handling system may further comprise a plurality of valves. Similarly to the exemplary arrangement shown in FIG. 4, the plurality of valves of FIG. 5 comprises a gas supply valve 72, a bypass valve 92, a fluid extraction valve 82 and an additional fluid extraction valve 87 which are each configured as described above for FIG. 4. The plurality of valves of FIG. 5 further comprises a second branch bypass valve 99. In the arrangement of FIG. 5, the bypass valve 92 is disposed in the first branch 93 of the bypass circuit 90. In other words, the bypass valve 92 may be configured to allow, restrict and/or prevent flow through the first branch 93 of the bypass conduit 90.

The second branch bypass valve 99 is disposed in the second branch 98 of the bypass conduit 90. In other words, the second branch bypass valve 99 may be configured to allow, restrict and/or prevent flow through the second branch 98 of the bypass conduit 90. In the production mode the second branch bypass valve 99 is closed to prevent fluid from flowing from the gas supply conduit 70 to the additional fluid transport conduit 85 via the second branch 98 of the bypass conduit 90. In the calibration mode, the second branch bypass valve 99 is closed to prevent fluid to flow from the gas supply conduit 70 to the additional fluid transport conduit 85 via the second branch 98 of the bypass conduit 90. In the additional calibration mode, the bypass valve 92 is closed to prevent fluid to flow from the gas supply conduit 70 to the fluid transport conduit 80 via the bypass conduit 90. In the additional calibration mode, the second branch bypass valve 99 is open to allow fluid to flow from the gas supply conduit 70 to the additional fluid transport conduit 85 via the second branch 98 of the bypass conduit 90.

The fluid handling system may further comprise a comparator (not shown). Under the additional calibration mode, the comparator may be configured to compare the measured flow of fluid in the additional fluid transport conduit 85 against the flow of fluid supplied by the flow controller 71. In particular, the comparator may be configured to compare the flow measured by the additional flow meter 86 with the flow supplied by the flow controller 71.

The fluid handling system optionally further comprise a meter calibration unit (not shown) configured to adjust the additional flow meter 86 based on the comparison. For example, if it is determined from the comparison that the additional flow meter 86 measurement is lower than expected, the additional flow meter 86 may be adjusted such that it gives the expected measurement value. Alternatively, or additionally, the fluid handling system may be configure to transmit an alert if the comparison indicates that the predetermined flow through the additional fluid transport conduit 85, based on the flow provided by the flow controller 71 in the additional calibration mode, and flow measured by the additional flow meter 86 do not match to within the predetermined range. In other words, the fluid handling system may be configured to alert a user if the additional flow meter 86 is not providing sufficiently accurate measurement values of flow through the additional fluid transport conduit 85. The user may then take action to adjust or replace the additional flow meter 86 as appropriate.

The fluid handling system optionally comprises a pressure sensor 73. The pressure sensor 73 may be disposed downstream of the flow controller 71, for example as shown in FIGS. 3, 4 and 5. The pressure sensor 73 is configured to measure the pressure of fluid. The pressure sensor 73 is desirably disposed in the gas supply conduit 70, as shown in FIG. 3. The pressure sensor 73 desirably enables determination of a relationship between pressure and flow rate in the gas flow conduit 70 for calibration of the flow controller 71. In this way, the pressure sensor 73 may be used to calibrate the flow controller 71. The flow controller 71 may then be used to calibrate the flow meter 81, for example by setting the fluid handling system in the calibration mode as described above.

The fluid handling system optionally further comprises a supply calibration unit (not shown) configured to adjust the flow controller 71 based on a comparison of the pressure measured by the pressure sensor 73 and a flow rate set by the flow controller 71. In other words, the supply calibration unit may be configured to automatically adjust the flow controller 71 if the pressure measured by the pressure sensor 73 is not within an acceptable range of the expected pressure based on the flow rate set by the flow controller 71, as this would indicate that the flow controller 71 has drifted out of calibration. The supply calibration unit may therefore be used to automatically calibrate the flow controller 71. Alternatively, or additionally, the fluid handling system may comprise an alert unit configure to alert a user if the if the pressure measured by the pressure sensor 73 is not within an acceptable range of the expected pressure based on the flow rate set by the flow controller 71. In this way, the user can manually take action to adjust or replace the flow controller 71 as appropriate.

Although the arrangements shown in FIGS. 4 and 5 each include only one additional fluid transport conduit 85, the arrangements may be modified to include more than one additional fluid transport conduit.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc.

Specifically, the lithographic apparatus may comprise the projection system PS configured to project the radiation beam B towards the region of the surface of a substrate W.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus.

Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use ambient (non-vacuum) conditions.

Although specific reference may have been made above to the use of embodiments of the invention in the context of optical lithography, it will be appreciated that the invention, where the context allows, is not limited to optical lithography.

Embodiments include the following numbered clauses:
1. A fluid handling system comprising:
a liquid confinement structure configured to confine immersion fluid to a space between at least a part of the liquid confinement structure and a surface of a substrate;
a gas supply conduit in fluid communication with the liquid confinement structure and configured to supply fluid to the space, the gas supply conduit having a flow controller configured to control the supply of gas from the gas supply conduit;
a fluid transport conduit in fluid communication with the liquid confinement structure and configured to transport fluid extracted from the space, the fluid transport conduit having a flow meter configured to measure the flow of gas in the fluid transport conduit; and
wherein under a calibration mode,
the gas supply conduit is in direct fluid communication with the fluid transport conduit via a bypass conduit, wherein the bypass conduit bypasses the liquid confinement structure; and
the gas supplied by the flow controller flows directly to the fluid transport conduit via the bypass conduit.
2. The system of clause 1, further comprising a comparator, wherein under the calibration mode, the comparator is configured to compare the measured flow of gas in the fluid transport conduit against the flow of gas supplied by the flow controller.
3. The system of clause 2, further comprising a meter calibration unit configured to adjust the flow meter based on the comparison.
4. The system of any preceding clause, wherein all or part of the bypass conduit is removable from the system, and wherein under the calibration mode the bypass conduit is attached to the system.
5. The system of any preceding clause, wherein under an production mode, the gas supplied by the flow controller flows to fluid transport conduit via the liquid confinement structure such that the flow meter is configured to measure the flow of extracted gas.
6. The system of clause 5, wherein all or part of the bypass conduit is removable from the system, and wherein under the calibration mode the bypass conduit is attached to the system and under the production mode the bypass conduit is detached from the system.
7. The system of clause 5 or 6, further comprising a plurality of valves configured to change the system between the production mode and the calibration mode.
8. The system of clause 7, wherein the plurality of valves comprises:
a gas supply valve disposed in the gas supply conduit downstream of the flow controller;
wherein, in the production mode the gas supply valve is open to allow gas to flow from the gas supply conduit into the space; and
wherein in the calibration mode, the gas supply valve is closed to prevent gas from flowing from the gas supply conduit into the space.
9. The system of clause 7 or 8, wherein the plurality of valves comprises:
a bypass valve disposed in the bypass conduit;
wherein, in the production mode the bypass valve is closed to prevent gas from flowing from the gas supply conduit to the fluid transport conduit via the bypass conduit; and
wherein in the calibration mode, the bypass valve is open to allow gas to flow from the gas supply conduit to the fluid transport conduit via the bypass conduit.
10. The system of any of clauses 7 to 9, wherein the plurality of valves comprises:
a fluid extraction valve disposed in the fluid transport conduit upstream of the flow meter;
wherein, in the production mode the fluid extraction valve is open to allow gas to flow from the space into the fluid transport conduit; and
wherein in the calibration mode, the fluid extraction valve is closed to prevent gas from flowing from the space into the fluid transport conduit.
11. The system of any preceding clause, further comprising a plurality of fluid extraction conduits in fluid communication with the liquid confinement structure and configured to extract fluid from the space and direct the extracted fluid to the fluid transport conduit.
12. The system of clause 11, wherein the plurality of fluid extraction conduits merge downstream of the space to form the fluid transport conduit.
13. The system of any of clauses 1 to 10, further comprising an additional fluid transport conduit in fluid communication with the liquid confinement structure and configured to transport fluid extracted from the space, the additional fluid transport conduit having an additional flow meter configured to measure the flow of gas in the additional fluid transport conduit.
14. The system of clause 13, wherein the fluid transport conduit and the additional fluid transport conduit are each configured to extract fluid from the space.
15. The system of clause 13 or 14, wherein under an additional calibration mode, the gas supply conduit is in direct fluid communication with the additional fluid transport conduit via the bypass conduit, wherein the bypass conduit bypasses the liquid confinement structure; and
the gas supplied by the flow controller flows directly to the additional fluid transport conduit via the bypass conduit.
16. The system of clause 13 or 14, wherein under an additional calibration mode, the gas supply conduit is in direct fluid communication with the additional fluid transport conduit via an additional bypass conduit, wherein the additional bypass conduit bypasses the liquid confinement structure and the bypass conduit; and
the gas supplied by the flow controller flows directly to the additional fluid transport conduit via the additional bypass conduit.
17. The system of clause 15 or 16, further comprising a comparator, wherein under the additional calibration mode, the comparator is configured to compare the measured flow of gas in the additional fluid transport conduit against the flow of gas supplied by the flow controller.
18. The system of any preceding clause, further comprising a pressure sensor disposed downstream of the flow controller, wherein the pressure sensor is configured to measure the pressure of gas in the gas supply conduit.
19. The system of clause 18, further comprising a supply calibration unit configured to adjust the flow controller based on a comparison of the pressure measured by the pressure sensor and a flow rate set by the flow controller.
20. The system of any preceding clause, wherein the bypass conduit comprises a flow restriction.
21. A method for calibrating a flow meter in a fluid handling system,
the fluid handling system comprising:
a liquid confinement structure configured to confine immersion fluid to a space between at least a part of the liquid confinement structure and a surface of a substrate;
a gas supply conduit in fluid communication with the liquid confinement structure and configured to supply fluid to the space, the gas supply conduit having a flow controller configured to control the supply of gas from the gas supply conduit;
a fluid transport conduit in fluid communication with the liquid confinement structure and configured to extract fluid from the space, the fluid transport conduit having the flow meter configured to measure the flow of gas in the fluid transport conduit;
the method comprising:
setting the system in calibration mode wherein the gas supply conduit is in direct fluid communication with the fluid transport conduit via a bypass conduit, wherein the bypass conduit bypasses the liquid confinement structure, and the gas supplied by the flow controller flows directly to the fluid transport conduit via the bypass conduit; and comparing the measured flow of gas in the fluid transport conduit against the flow of gas supplied by the flow controller.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A fluid handling system comprising:
a liquid confinement structure configured to confine immersion fluid to a space between at least a part of the liquid confinement structure and a surface of a substrate;
a gas supply conduit in fluid communication with the liquid confinement structure and configured to supply fluid to the space, the gas supply conduit having a flow controller configured to control the supply of gas from the gas supply conduit;
a fluid transport conduit in fluid communication with the liquid confinement structure and configured to transport fluid extracted from the space, the fluid transport conduit having a flow meter configured to measure the flow of gas in the fluid transport conduit; and
wherein under a calibration mode,
the gas supply conduit is in direct fluid communication with the fluid transport conduit via a bypass conduit, wherein the bypass conduit bypasses the liquid confinement structure; and
the gas supplied by the flow controller flows directly to the fluid transport conduit via the bypass conduit.

2. The system of claim 1, further comprising a comparator, wherein under the calibration mode, the comparator is configured to compare the measured flow of gas in the fluid transport conduit against the flow of gas supplied by the flow controller.

3. The system of claim 2, further comprising a meter calibration unit configured to adjust the flow meter based on the comparison.

4. The system of claim 1, wherein all or part of the bypass conduit is removable from the system, and wherein under the calibration mode the bypass conduit is attached to the system, and/or wherein under a production mode, the gas supplied by the flow controller flows to the fluid transport conduit via the liquid confinement structure such that the flow meter is configured to measure the flow of extracted gas.

5. The system of claim 4, wherein all or part of the bypass conduit is removable from the system, and wherein under the calibration mode the bypass conduit is attached to the system and under a production mode the bypass conduit is detached from the system.

6. The system of claim 4, further comprising a plurality of valves configured to change the system between a production mode and the calibration mode.

7. The system of claim 6, wherein the plurality of valves comprises:
a gas supply valve disposed in the gas supply conduit downstream of the flow controller;
wherein, in the production mode, the gas supply valve is open to allow gas to flow from the gas supply conduit into the space; and
wherein, in the calibration mode, the gas supply valve is closed to prevent gas from flowing from the gas supply conduit into the space, and/or
wherein the plurality of valves comprises:
a bypass valve disposed in the bypass conduit;
wherein, in the production mode, the bypass valve is closed to prevent gas from flowing from the gas supply conduit to the fluid transport conduit via the bypass conduit; and
wherein, in the calibration mode, the bypass valve is open to allow gas to flow from the gas supply conduit to the fluid transport conduit via the bypass conduit, and/or
wherein the plurality of valves comprises:
a fluid extraction valve disposed in the fluid transport conduit upstream of the flow meter;
wherein, in the production mode, the fluid extraction valve is open to allow gas to flow from the space into the fluid transport conduit; and
wherein, in the calibration mode, the fluid extraction valve is closed to prevent gas from flowing from the space into the fluid transport conduit.

8. The system of claim 1, further comprising a plurality of fluid extraction conduits in fluid communication with the liquid confinement structure and configured to extract fluid from the space and direct the extracted fluid to the fluid transport conduit or further comprising an additional fluid transport conduit in fluid communication with the liquid confinement structure and configured to transport fluid extracted from the space, the additional fluid transport conduit having an additional flow meter configured to measure flow of gas in the additional fluid transport conduit.

9. The system of claim 8, comprising the plurality of fluid extraction conduits, wherein the plurality of fluid extraction conduits merge downstream of the space to form the fluid transport conduit or
comprising the additional fluid transport conduit, wherein the fluid transport conduit and the additional fluid transport conduit are each configured to extract fluid from the space.

10. The system of claim 8, comprising the additional fluid transport conduit and wherein under an additional calibration mode,
the gas supply conduit is in direct fluid communication with the additional fluid transport conduit via the bypass conduit, wherein the bypass conduit bypasses the liquid confinement structure; and
the gas supplied by the flow controller flows directly to the additional fluid transport conduit via the bypass conduit, or
wherein under an additional calibration mode,
the gas supply conduit is in direct fluid communication with the additional fluid transport conduit via an additional bypass conduit, wherein the additional bypass conduit bypasses the liquid confinement structure and the bypass conduit; and
the gas supplied by the flow controller flows directly to the additional fluid transport conduit via the additional bypass conduit.

11. The system of claim 10, further comprising a comparator, wherein under the additional calibration mode, the comparator is configured to compare the measured flow of gas in the additional fluid transport conduit against the flow of gas supplied by the flow controller.

12. The system of claim 1, further comprising a pressure sensor disposed downstream of the flow controller, wherein the pressure sensor is configured to measure the pressure of gas in the gas supply conduit.

13. The system of claim 12, further comprising a supply calibration unit configured to adjust the flow controller based on a comparison of the pressure measured by the pressure sensor and a flow rate set by the flow controller.

14. The system of claim 1, wherein the bypass conduit comprises a flow restriction.

15. A method for calibrating a flow meter in a fluid handling system, the fluid handling system comprising:
a liquid confinement structure configured to confine immersion fluid to a space between at least a part of the liquid confinement structure and a surface of a substrate;
a gas supply conduit in fluid communication with the liquid confinement structure and configured to supply fluid to the space, the gas supply conduit having a flow controller configured to control the supply of gas from the gas supply conduit;
a fluid transport conduit in fluid communication with the liquid confinement structure and configured to extract fluid from the space, the fluid transport conduit having the flow meter configured to measure a flow of gas in the fluid transport conduit;
the method comprising:
setting the system in calibration mode wherein the gas supply conduit is in direct fluid communication with the fluid transport conduit via a bypass conduit, wherein the bypass conduit bypasses the liquid confinement structure, and the gas supplied by the flow controller flows directly to the fluid transport conduit via the bypass conduit; and
comparing the measured flow of gas in the fluid transport conduit against the flow of gas supplied by the flow controller.

16. The method of claim 15, wherein all or part of the bypass conduit is removable from the system, and comprising, under the calibration mode, attaching the bypass conduit to the system from an unattached state.

17. The method of claim 15, wherein under a production mode, the gas supplied by the flow controller flows to the fluid transport conduit via the liquid confinement structure and comprising measuring that flow of extracted gas using the flow meter.

18. The method of claim 15, wherein all or part of the bypass conduit is removable from the system, and comprising, for a production mode, detaching the bypass conduit from the system.

19. The method of claim 15, further using a plurality of valves to change the system between a production mode and the calibration mode.

20. The method of claim 15, further comprising measuring the pressure of gas in the gas supply conduit at a location downstream of the flow controller.
